(19) United States
(12) Patent Application Publication
(10) Pub. No.: US 2010/0181944 A1
(43) Pub. Date: Jul. 22, 2010

(54) MICROMECHANICAL COMPONENT AND METHOD FOR OPERATING A MICROMECHANICAL COMPONENT

(76) Inventors: Wolfram Bauer, Tuebingen (DE); Johannes Classen, Reutlingen (DE)

Correspondence Address: KENYON & KENYON LLP, ONE BROADWAY, NEW YORK, NY, 10004, US

(21) Appl. No.: 12/452,562

(22) PCT Filed: Jun. 16, 2008
(86) PCT No.: PCT/EP2008/057528

§ 371 Date: Mar. 25, 2010

(30) Foreign Application Priority Data
Jul. 16, 2007 (DE) 10 2007 033 002.4

(51) Int. Cl. H01L 41/04; H02N 1/00

(52) U.S. Cl. 318/116; 310/309

(57) ABSTRACT

A micromechanical component includes a first electrode and a second electrode, the first electrode being moveable relative to the second electrode in a main direction of movement, and the first electrode and/or the second electrode being configured such that a movement of the first electrode parallel to the main direction of movement results in a modification of the average distance in a region of overlap of the projection of the first electrode with the projection of the second electrode, both perpendicular to the main direction of movement and in a main plane of extension.

### BACKGROUND OF THE INVENTION

1. Field of the Invention

The present invention relates to a micromechanical component having a fixed structure and a seismic mass.

2. Description of Related Art

Such micromechanical components are generally known. For example, U.S. Pat. No. 5,025,346 describes a micromechanical component that has a carrier substrate and a seismic mass, the carrier substrate including second electrodes and the seismic mass including first electrodes, and it being possible to move the seismic mass in a main direction of movement relative to the carrier substrate. The second electrodes and the first electrodes overlap in a direction that is perpendicular to the main direction of movement in a main plane of extension of the carrier substrate. A movement of the seismic mass results in a change in the overlapping surface, but the average distance along the region of overlap between first electrodes and second electrodes remains constant continually. The natural frequency of the seismic mass is determined by the mass of the seismic mass, the form of the seismic mass, and by suspension elements of the seismic mass, and cannot be modified after the manufacturing process has concluded.

### BRIEF SUMMARY OF THE INVENTION

Compared to the related art, the micromechanical component and the method for operating a micromechanical component according to the present invention have the advantage that an effective spring stiffness and a vibrational behavior of the first electrodes and/or second electrodes may be modified by applying a constant electric potential difference between the second electrodes and the first electrodes. Thus, temperature dependencies in the vibrational behavior of the first and/or second electrodes are preferably compensated, so that the micromechanical component is able to function as a clock generator. The change in the average distance in the region of overlap between the first electrodes and the second electrodes due to the movement of the first electrodes along the main direction of movement, i.e., which essentially also proceeds parallel to the main extension of the first and second electrodes, results in an additional positive feedback term in an analytical expression for calculating the effective spring stiffness. The effective spring stiffness thus results from the sum of the spring stiffness and an additional summand that essentially has a quadratic dependency on a potential difference between the first electrode and the second electrode. Consequently, it is possible to modify the effective spring stiffness and thus also the vibrational behavior, i.e., in particular also the natural frequency, of the first electrodes relative to the second electrodes preferably by applying a constant potential difference as a positive feedback voltage. In particular, a suitable adjustment of the positive feedback voltage makes it possible to achieve a vibration temperature stability that is significantly higher than that of the related art, which means in particular that it is possible to use the micromechanical component as a precise clock generator. Preferably as a clock generator in a communication device, in particular for CAN communication in the automotive sector.

According to an example embodiment of the micromechanical component according to the present invention, the first and/or the second electrode is integrally connected to a seismic mass and/or a fixed structure. Thus, it is advantageously possible to implement micromechanical components having first and second electrodes on a first and second seismic mass, respectively, which move relative to each other, or micromechanical components having first and second electrodes that are connected to a seismic mass and a fixed structure, respectively. In the following the second electrode is called a fixed electrode of a fixed structure and the first electrode is called a counter-electrode of a seismic mass.

According to an example embodiment of the micromechanical component according to the present invention, a movement of the seismic mass parallel to the main direction of movement brings about a change in the size of the region of overlap between the counter-electrode and the fixed electrode. This advantageously allows for a positive feedback comb actuator, which activates a movement of the seismic mass relative to the fixed structure by applying suitable electric actuating potential differences between the counter-electrodes and the fixed electrodes. In addition to exciting vibrations, the superposition of the actuating potential difference and the positive feedback voltage allows for the simultaneous modification of the effective spring stiffness.

According to an additional example embodiment of the micromechanical component according to the present invention, when the seismic mass is in a neutral position, the projection of the counter-electrode and the projection of the fixed electrode are respectively provided in a manner that is perpendicular to the main direction of movement and is overlapping and/or overlap-free in the main plane of extension. Advantageously, a neutral overlap results in a more efficient excitation of vibrations of the seismic mass from the neutral position, since in the neutral position, the overlap already leads to the formation of a greater capacitance between counter-electrode and fixed electrode relative to an overlap-free neutral position. A micromechanical component in which the counter-electrodes and second electrodes do not overlap in the neutral position, overlapping only in a deflection position, simplifies the process for manufacturing the electrode system significantly because minimal distances that are caused by technology in the manufacture of the structure do not influence the distances of the counter-electrodes and fixed electrodes that are set apart in the manufacturing process.

According to an additional example embodiment of the micromechanical component according to the present invention, the projection is designed in a manner perpendicular to the main plane of extension of the counter-electrode and/or the fixed electrode and is designed as a trapezoid, as a triangle, as an oval, and/or in parabolic form, in particular the fixed electrode being designed essentially as a negative form of the corresponding counter-electrode. Preferably, an arrangement of the counter-electrode and fixed electrode is also provided, in which the projection of the counter-electrode is essentially designed as a negative form of the projection of the corresponding fixed electrode. Advantageously, the corresponding electrode forms bring about, in a simple manner, the change in the average distance between the counter-electrode and fixed electrode in the region of overlap during a movement of the seismic mass along the main direction of movement. In particular, the different electrode forms and/or variations in the dimensioning of the electrode form allow for the modification region, which may be adjusted by the positive feedback voltage, to be adjusted to the required vibration properties.

According to an additional example embodiment of the micromechanical component according to the present invention, the counter-electrode and the fixed electrode are implemented such that the vibrational behavior and the effective spring stiffness of the seismic mass are a function of a constant potential difference between the counter-electrode and the fixed electrode. Advantageously, the vibrational behavior and the effective spring stiffness may thus be modified by applying a positive feedback voltage, in particular during the running vibration operation of the seismic mass. In a particularly advantageous manner, the modification of the vibrational behavior and of the effective spring stiffness allows for the effective spring stiffness to be dynamically modified, preferably by an integrated electric circuit and particularly preferably resulting in a constant compensation of the temperature dependency of the vibration.

According to an additional example embodiment of the micromechanical component according to the present invention, the counter-electrode and the fixed electrode are implemented in such a manner that the micromechanical component includes an actuation comb or an actuation detection comb, in particular for a rotation-rate sensor. Advantageously, this allows for the temperature of a rotation-rate sensor to be stabilized, which means the rotation-rate sensor may be used as a precise clock generator, in particular for communication devices that require an exact timing of transmission cycles and/or communicate via CAN interfaces.

An additional subject matter of the present invention is a method for operating a micromechanical component, a movement of the seismic mass relative to the fixed structure parallel to the main direction of movement being induced via electrostatic forces between the counter-electrode and the fixed electrode. Advantageously, the vibration of the seismic mass relative to the fixed structure is thus induced by applying the drive voltage difference.

According to an additional example embodiment for operating a micromechanical component, by moving the seismic mass relative to the fixed structure parallel to the main direction of movement, the average distance is modified in the region of overlap of the projection of the counter-electrode with the projection of the fixed electrode, both perpendicular to the main direction of movement and in the main plane of extension. Advantageously, an additional positive feedback term thus results in the analytical expression for the effective spring stiffness, so that a modification of the vibrational behavior and the effective spring stiffness is made possible, which is in particular independent of the suspension elements of the seismic mass and may be modified during the vibration operation. Particularly advantageously, this causes a shift in the natural frequency of the seismic mass and/or a temperature compensation of the vibration.

According to an additional example embodiment for operating a micromechanical component, the vibrational behavior of the seismic mass is adjusted via additional electrostatic forces between the counter-electrode and the fixed electrode, which in particular are brought about by applying a suitable potential difference between the counter-electrode and the fixed electrode. Thus, advantageously, an adjustment of the effective spring stiffness and of the vibrational behavior of the seismic mass is made possible by the positive feedback voltage. Particularly advantageously, superposing the positive feedback voltage and the drive voltage difference allows for the vibration to be adjusted and for the vibration adjustment to be dynamically adapted during the vibration process.

An additional subject matter of the present invention is a use of a micromechanical component according to the present invention as a clocking element, preferably as a temperature-stabilized clocking element, particularly preferably as a clock generator for a CAN frequency in the automotive sector.

Exemplary embodiments of the present invention are depicted in the drawing and described in greater detail in the description below.

### BRIEF DESCRIPTION OF SEVERAL VIEWS OF THE DRAWING

FIG. 1 shows a schematic top view of a component according to the present invention in accordance with a first specific embodiment, a seismic mass of the micromechanical component being shown in a neutral position.

FIG. 2 shows an additional schematic top view of a component according to the present invention in accordance with the first specific embodiment, the seismic mass being shown in a deflection position.

FIG. 3 shows a schematic top view of a component according to the present invention in accordance with a second specific embodiment.

FIG. 4 shows a schematic top view of a component according to the present invention in accordance with a third specific embodiment.

### DETAILED DESCRIPTION OF THE INVENTION

The reference numerals in the figures illustrating the different example embodiments of the micromechanical component according to the present invention respectively label identical elements of the component according to the present invention and therefore are not repeatedly labeled in each instance.

FIG. 1 illustrates an example embodiment of a micromechanical component 1 according to the present invention, micromechanical component 1 featuring a fixed structure 3 and a seismic mass 2, fixed structure 3 having fixed electrodes 5 or second electrodes 5 and seismic mass 2 having counter-electrodes 4 or first electrodes and it being possible to move seismic mass 2 relative to fixed structure 3 in a main direction of movement 6. The illustration shows micromechanical component 1 in a neutral position 8, the projection of counter-electrode 4 and the projection of fixed electrode 5 respectively being overlap-free in a direction perpendicular to main direction of movement 6 and in main plane of extension 7. Counter-electrodes 4 and fixed electrodes 5 are designed such that a movement of seismic mass 2 parallel to main direction of movement 6 in the direction of the fixed structure results in a modification of average distance 11, in region of overlap 14 of the projection of counter-electrode 4 with the projection of fixed electrode 5, perpendicular to main direction of movement 6 and in a main plane of extension 7, in each instance. The projection of at least one counter-electrode and/or fixed electrode 4, 5 perpendicular to main plane of extension 7 is designed as a trapezoid. Fixed structure 3 is optionally provided as an additional seismic mass, fixed electrode 5 comprising movable second electrode 5.

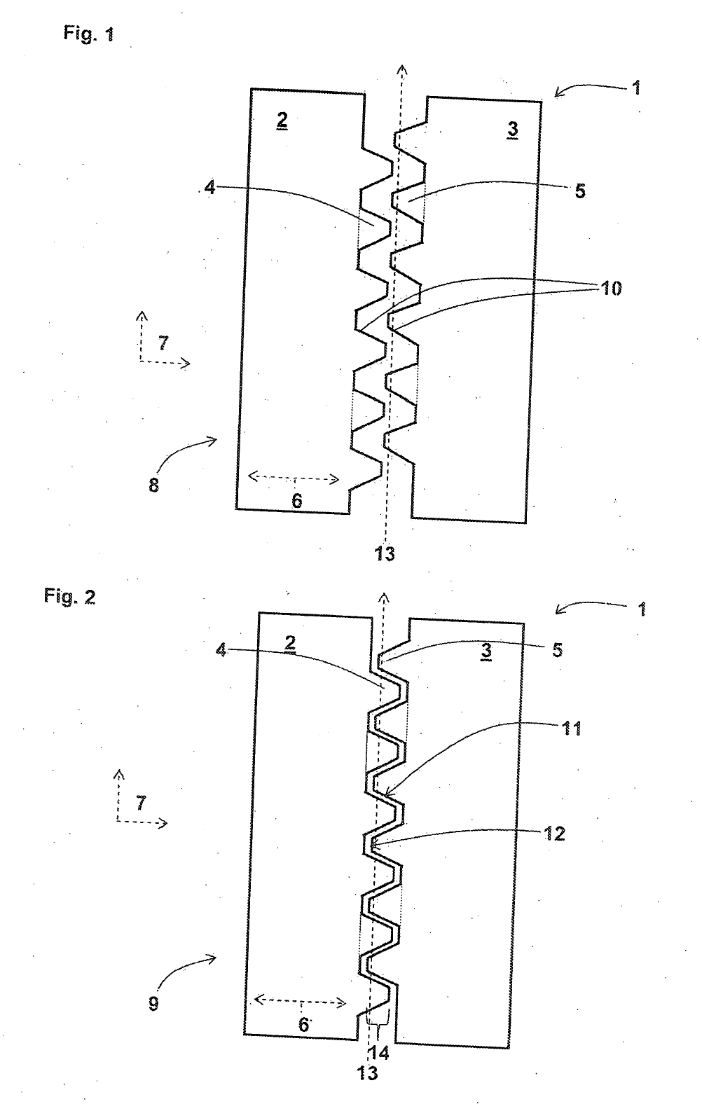

FIG. 2 illustrates a schematic top view of a micromechanical component 1 according to the present invention, in accordance with the first example embodiment, seismic mass 2 not being in neutral position 8 in accordance with the illustration in FIG. 1, however, and instead being in a deflection position 9. Thus, counter-electrodes 4 have region of overlap 14 with fixed electrodes 5. Applying two suitable electric potentials, i.e., a drive voltage, at counter-electrodes 4 and at fixed electrodes 5 induces an attracting electrostatic force between counter-electrodes and fixed electrodes 4, 5, resulting in an action of force between seismic mass 2 and fixed structure 3 parallel to main direction of movement 6. In this context, counter-electrodes 4 and fixed electrodes 5 are designed such that a movement of seismic mass 2 parallel to main direction of movement 6 results in a change to average distance 11 between counter-electrode 4 and fixed electrode 5 in region of overlap 14. Superposing the drive voltage with a positive feedback voltage between counter-electrodes and fixed electrodes 4, 5 thus causes a change in the effective spring stiffness and in the vibrational behavior of seismic mass 2 in the event of a movement of seismic mass 2 relative to fixed structure 3 parallel to main direction of movement 6.

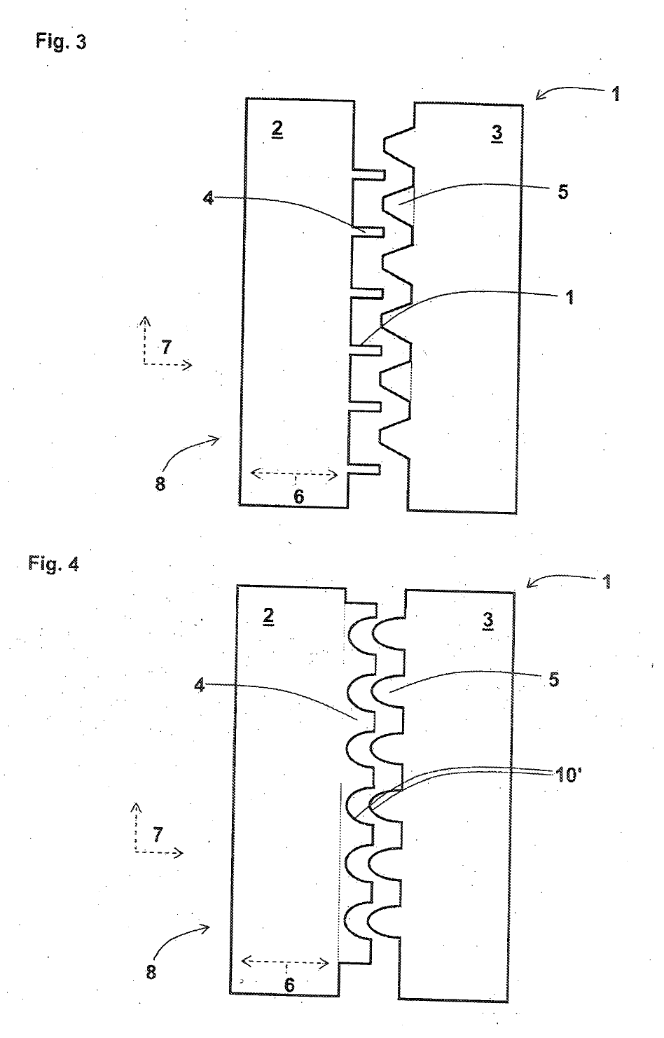

In FIG. 3, a schematic top view of a micromechanical component according to the present invention in accordance with a second example embodiment is shown, the illustration essentially corresponding to that of FIG. 1 with only the projection of at least one counter-electrode 4 perpendicular to main plane of extension 7 having a rectangular form, while the projection of at least one fixed electrode is designed as a trapezoid. Preferably an arrangement is provided, whereby the projection of the counter-electrode is designed as a trapezoid and the projection of the fixed electrode is designed as a rectangle.

In FIG. 4, a schematic top view of a micromechanical component according to the present invention in accordance with a third example embodiment is shown, the illustration essentially also corresponding to that of FIG. 1 with only the projection of at least one fixed electrode 5 perpendicular to main plane of extension 7 being designed as an oval and/or the projection of at least one counter-electrode 4 having a negative form of second electrode form 5. Alternatively, an arrangement is provided, whereby the projection of counter-electrode 4 is designed as an oval and/or a projection of fixed electrode 5 has a negative form of counter-electrode 4.

1-11. (canceled)

12. A micromechanical component, comprising:
a first electrode having at least one projection; and
a second electrode having at least one projection;
wherein the first electrode is configured to be moveable relative to the second electrode in a predefined main direction of movement, and wherein at least one of the first electrode and the second electrode is configured such that a movement of the first electrode parallel to the main direction of movement results in a modification of an average distance between the projection of the first electrode and the projection of the second electrode in a region of overlap of the projection of the first electrode with the projection of the second electrode, wherein the average distance is measured perpendicular to the main direction of movement and in a main plane of extension of the first and second electrodes.

13. The micromechanical component as recited in claim 12, wherein at least one of the first electrode and the second electrode is configured such that a movement of at least one of the first electrode and the second electrode parallel to the main direction of movement results in a change in the size of the region of overlap between the first electrode and the second electrode.

14. The micromechanical component as recited in claim 13, wherein in a predefined neutral position of the first electrode, the projection of the first electrode and the projection of the second electrode do not overlap one another along a direction perpendicular to the main direction of movement and in the main plane of extension.

15. The micromechanical component as recited in claim 14, wherein the projections of the first and second electrodes are configured as a one of a trapezoid, a triangle, an oval, or in a parabolic form, and wherein the second electrode is configured as a complement of the first electrode.

16. The micromechanical component as recited claim 13, wherein the effective spring stiffness of a suspension of the first electrode is a function of a constant potential difference between the first electrode and the second electrode.

17. The micromechanical component as recited in claim 13, wherein the micromechanical component includes an actuation comb for a rotation-rate sensor.

18. The micromechanical component as recited in claim 13, wherein the first electrode is integrally connected to a seismic mass and the second electrode is integrally connected to a fixed structure.

19. A method for operating a micromechanical component, comprising:
providing a first electrode having at least one projection and a second electrode having at least one projection, wherein the first electrode is configured to be moveable relative to the second electrode in a predefined main direction of movement; and
inducing a movement of the first electrode relative to the second electrode parallel to the main direction of movement by electrostatic forces between the first electrode and the second electrode.

20. The method as recited in claim 19, wherein a movement of the first electrode parallel to the main direction of movement results in a modification of an average distance between the projection of the first electrode and the projection of the second electrode in a region of overlap of the projection of the first electrode with the projection of the second electrode, wherein the average distance is measured perpendicular to the main direction of movement and in a main plane of extension of the first and second electrodes.

21. The method as recited in claim 19, wherein the first electrode is integrally connected to a seismic mass and the second electrode is integrally connected to a fixed structure, and wherein the vibrational behavior of the seismic mass is adjusted by additional electrostatic forces between the first electrode and the second electrode brought about by applying a specified potential difference between the first electrode and the second electrode.

22. The method as recited in claim 19, wherein the micromechanical component is utilized as a temperature-stabilized clocking element.
